(19) United States
(12) Patent Application Publication
(10) Pub. No.: US 2015/0138452 A1
(43) Pub. Date: May 21, 2015

(54) TOUCH SCREEN WITH CONDUCTIVE MESH UNDER POLARIZER

(71) Applicant: Robert J. Petcavich, The Woodlands, TX (US)

(72) Inventor: Robert J. Petcavich, The Woodlands, TX (US)

(73) Assignee: UNI-PIXEL DISPLAYS, INC., The Woodlands, TX (US)

(21) Appl. No.: 14/083,714

(22) Filed: Nov. 19, 2013

(51) Int. Cl. G06F 3/041; H01L 27/32; G02F 1/1335; G02B 5/30; G02F 1/1333; G02F 1/1368

(52) U.S. Cl. CPC G06F 3/0412; G02F 1/13338; G02F 1/1368; G02F 1/133528; G02F 1/1336; G02B 5/3058; H01L 27/323
USPC 349/12

(57) ABSTRACT

A touch screen includes a front linear polarizer, a touch sensor, and a front display substrate. The touch sensor includes a first conductive mesh disposed on a top side of an optically isotropic substrate and a second conductive mesh disposed on a bottom side of the optically isotropic substrate. A top side of the first conductive mesh is coupled to a bottom side of the front linear polarizer. A bottom side of the second conductive mesh is coupled to a top side of the front display substrate.

### BACKGROUND OF THE INVENTION

An electronic device with a touch screen allows a user to control the device by touch. The user may interact directly with objects depicted on a display device by touch or gestures. Touch screens are commonly found in consumer systems, commercial systems, and industrial systems including, but not limited to, smartphones, tablet computers, laptop computers, desktop computers, kiosks, monitors, televisions, portable gaming devices, and gaming consoles.

A touch screen includes a touch sensor configured to sense touch. The touch sensor includes a pattern of conductive lines disposed on a substrate. Flexographic printing is a rotary relief printing process that transfers an image to a substrate. A flexographic printing process may be adapted for use in the manufacture of touch sensors.

### BRIEF SUMMARY OF THE INVENTION

According to one aspect of one or more embodiments of the present invention, a touch screen includes a front linear polarizer, a touch sensor, and a front display substrate. The touch sensor includes a first conductive mesh disposed on a top side of an optically isotropic substrate and a second conductive mesh disposed on a bottom side of the optically isotropic substrate. A top side of the first conductive mesh is coupled to a bottom side of the front linear polarizer. A bottom side of the second conductive mesh is coupled to a top side of the front display substrate.

According to one aspect of one or more embodiments of the present invention, a touch screen includes a front linear polarizer, a touch sensor, and a front display substrate. The touch sensor includes a first conductive mesh disposed on a top side of the front display substrate and a second conductive mesh disposed on a bottom side of the front display substrate. A top side of the first conductive mesh is coupled to a bottom side of the front linear polarizer.

According to one aspect of one or more embodiments of the present invention, a touch screen includes a front linear polarizer, a touch sensor, and a front display substrate. The touch sensor includes a first conductive mesh disposed on a bottom side of the front linear polarizer and a second conductive mesh disposed on a top side of the front display substrate. A bottom side of the first conductive mesh is coupled to a top side of the second conductive mesh.

According to one aspect of one or more embodiments of the present invention, a touch screen includes a circular polarizer, a touch sensor, and a front display substrate. The touch sensor includes a first conductive mesh disposed on a top side of a substrate and a second conductive mesh disposed on a bottom side of the substrate. A top side of the first conductive mesh is coupled to a bottom side of the circular polarizer. A bottom side of the second conductive mesh is coupled to a top side of the front display substrate.

According to one aspect of one or more embodiments of the present invention, a touch screen includes a circular polarizer, a touch sensor, and a front display substrate. The touch sensor includes a first conductive mesh disposed on a top side of the front display substrate and a second conductive mesh disposed on a bottom side of the front display substrate. A top side of the first conductive mesh is coupled to a bottom side of the circular polarizer.

According to one aspect of one or more embodiments of the present invention, a touch screen includes a circular polarizer, a touch sensor, and a front display substrate. The touch sensor includes first conductive mesh disposed on a bottom side of the circular polarizer and a second conductive mesh disposed on a top side of the front display substrate. A bottom side of the first conductive mesh is coupled to a top side of the second conductive mesh.

Other aspects of the present invention will be apparent from the following description and claims.

### BRIEF DESCRIPTION OF THE DRAWINGS

FIG. 1 shows a cross section of a conventional liquid crystal display touch screen with a discrete touch sensor solution.

FIG. 2 shows a cross section of a conventional organic light-emitting diode touch screen with a discrete touch sensor solution.

FIG. 3 shows a schematic view of a conventional touch screen with a discrete touch sensor solution as part of a computing system.

FIG. 4 shows a functional representation of a touch sensor as part of a touch screen in accordance with one or more embodiments of the present invention.

FIG. 5A shows a cross-section of a touch sensor with a single substrate in accordance with one or more embodiments of the present invention.

FIG. 5B shows a cross-section of a touch sensor with two substrates in accordance with one or more embodiments of the present invention.

FIG. 6 shows a first conductive mesh disposed on a substrate in accordance with one or more embodiments of the present invention.

FIG. 7 shows a second conductive mesh disposed on a substrate in accordance with one or more embodiments of the present invention.

FIG. 8 shows a portion of a touch sensor in accordance with one or more embodiments of the present invention.

FIG. 9 shows a flexographic printing system in accordance with one or more embodiments of the present invention.

FIG. 10 shows a cross section of a liquid crystal display touch screen with conductive mesh under polarizer in accordance with one or more embodiments of the present invention.

FIG. 11 shows a cross section of a liquid crystal display touch screen with conductive mesh under polarizer in accordance with one or more embodiments of the present invention.

FIG. 12 shows a cross section of a liquid crystal display touch screen with conductive mesh under polarizer in accordance with one or more embodiments of the present invention.

FIG. 13 shows a cross section of an organic light-emitting diode touch screen with a conductive mesh under polarizer in accordance with one or more embodiments of the present invention.

FIG. 14 shows a cross section of an organic light-emitting diode touch screen with a conductive mesh under polarizer in accordance with one or more embodiments of the present invention.

FIG. 15 shows a cross section of an organic light-emitting diode touch screen with a conductive mesh under polarizer in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

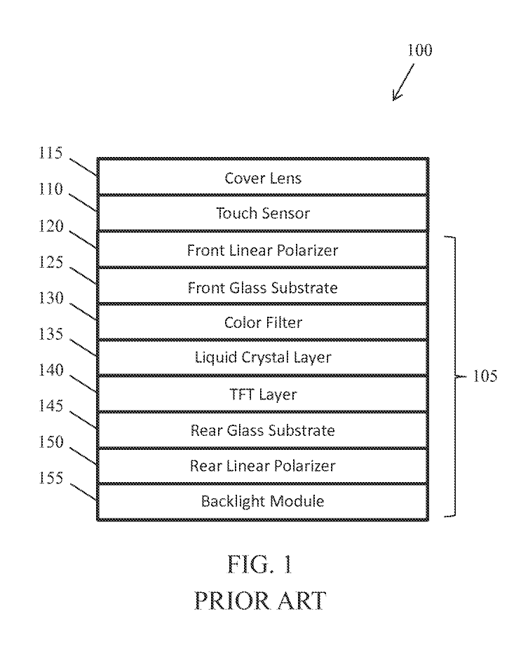

FIG. 1 shows a cross section of a conventional liquid crystal display (“LCD”) touch screen with a discrete touch sensor solution. Typically, an original equipment manufacturer (“OEM”) procures an LCD 105 sub-assembly, a touch sensor 110 sub-assembly, and a cover lens 115. The OEM assembles the procured components in a mechanical chassis (not shown) to form an LCD touch screen 100 suitable for use in consumer, commercial, or industrial applications or designs. Generally, LCD 105 serves an output function, touch sensor 110 serves an input function, and cover lens 115 protects the underlying components of LCD touch screen 100.

A top side of cover lens 115 faces the user and is typically composed of glass. A bottom side of cover lens 115 is coupled to a top side of touch sensor 110 by an optically clear adhesive (not shown). A bottom side of touch sensor 110 is coupled to a top side of a front linear polarizer 120 by an optically clear adhesive (not shown). Front linear polarizer 120 may be a glossy or an anti-glare (matte finish) polarizer rotated 90 degrees with respect to a rear linear polarizer 150, thereby forming a cross-polarized pair. A bottom side of front linear polarizer 120 is coupled to a top side of a front glass substrate 125 by an optically clear adhesive (not shown). A color filter 130 is disposed on a bottom side of front glass substrate 125. Color filter 130 includes a plurality of red, green, and blue (“RGB”) sub-pixel patterns (not shown). A liquid crystal layer 135 is disposed between a bottom side of color filter 130 and a top side of thin-film transistor (“TFT”) layer 140. TFT layer 140 is disposed on a top side of a rear glass substrate 145 and is configured to selectively drive sub-pixel electrodes (not shown) of liquid crystal layer 135. A top side of rear linear polarizer 150 is coupled to a bottom side of rear glass substrate 145 by an optically clear adhesive (not shown). A top side of a backlight module 155 is coupled to a bottom side of rear linear polarizer 150. Backlight module 155 typically includes a light source such as an electroluminescent lamp, a cold cathode fluorescent lamp, or a light-emitting diode (“LED”) array.

In operation, backlight module 155 produces visible light that substantially passes through rear linear polarizer 150. Because front linear polarizer 120 is rotated 90 degrees with respect to rear linear polarizer 150, the light produced by backlight module 155 is substantially blocked by front linear polarizer 120. When a given sub-pixel (not shown) is to be displayed, TFT layer 140 drives a sub-pixel electrode (not shown) that drives a corresponding sub-pixel (not shown) of liquid crystal layer 135. The driven liquid crystal sub-pixel (not shown) twists nematically and the polarization of the light is changed such that it can pass through color filter 130 and front linear polarizer 120. The color filtered light of the driven sub-pixel (not shown) passes through front linear polarizer 120 and is visible to the user.

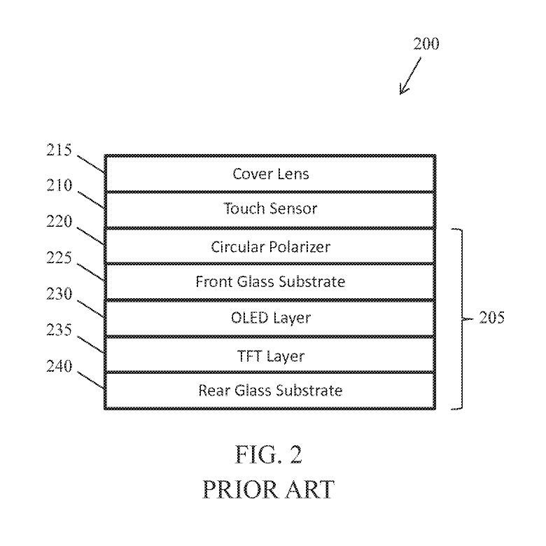

FIG. 2 shows a cross section of a conventional organic light-emitting diode (“OLED”) touch screen with a discrete touch sensor solution. Typically, an OEM procures an OLED display 205 sub-assembly, a touch sensor 210 sub-assembly, and a cover lens 215. The OEM assembles the procured components in a mechanical chassis (not shown) to form an OLED touch screen 200 suitable for use in consumer, commercial, or industrial applications or designs. Generally, OLED display 205 serves an output function, touch sensor 210 serves an input function, and cover lens 215 protects the underlying components of OLED touch screen 200.

A top side of cover lens 215 faces the user and is typically composed of glass. A bottom side of cover lens 215 is coupled to a top side of touch sensor 210 by an optically clear adhesive (not shown). A bottom side of touch sensor 210 is coupled to a top side of circular polarizer 220 by an optically clear adhesive (not shown). Circular polarizer 220 may be a glossy or an anti-glare (matte finish) polarizer. A bottom side of circular polarizer 220 is coupled to a top side of a front glass substrate 225 by an optically clear adhesive (not shown). An OLED layer 230 is disposed between a bottom side of front glass substrate 225 and a top side of a TFT layer 235. TFT layer 235 is disposed on a top side of a rear glass substrate 240 and is configured to selectively drive OLED sub-pixels (not shown).

In operation, OLED display 205 emits light through electro-phosphorescence. TFT layer 235 selectively drives OLED sub-pixels (not shown) that, when driven, emit light. The color of the light emitted depends on the type of organic molecule in the emissive layer (not shown) of OLED layer 230. Thus, a plurality of RGB sub-pixels (not shown) may be formed by using organic molecules that emit red, green, or blue light respectively.

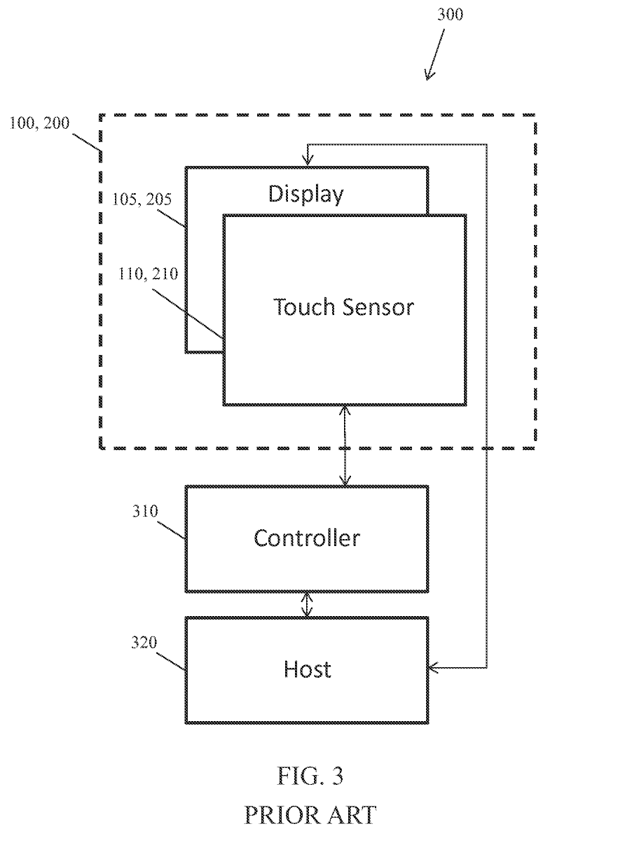

FIG. 3 shows a schematic view of a conventional touch screen with a discrete touch sensor solution as part of a computing system. Computing system 300 may be a consumer computing system, a commercial computing system, or an industrial computing system including, but not limited to, a smartphone, a tablet computer, a laptop computer, a desktop computer, a monitor, a kiosk, a television, a portable gaming device, a gaming console, or any other system suitable for use with touch screen 100 or 200.

Computing system 300 includes one or more printed circuit boards (not shown) and/or one or more flex circuits (not shown) on which one or more processors (not shown) and/or system memory (not shown) may be disposed. Each of the one or more processors may be a single-core processor (not shown) or a multi-core processor (not shown). Multi-core processors (not shown) typically include a plurality of processor cores (not shown) disposed on the same physical die (not shown) or a plurality of processor cores (not shown) disposed on multiple die (not shown) that are disposed within the same mechanical package (not shown).

Computing system 300 may include one or more input/output devices (not shown), one or more local storage devices (not shown) including solid-state memory (not shown), a fixed disk drive (not shown), a fixed disk drive array (not shown), or any other non-transitory computer readable medium (not shown), a network interface device (not shown), and/or one or more network storage devices (not shown) including network-attached storage devices (not shown) and cloud-based storage devices (not shown).

Touch screen 100 (or 200) includes an LCD 105 (or OLED display 205) and a touch sensor 110 (or 210) that overlays at least a portion of a viewable area of LCD 105 (or OLED display 205). Controller 310 electrically drives touch sensor 110 (or 210). Touch sensor 110 (or 210) senses touch and conveys information (capacitance, resistivity, or piezo) corresponding to the sensed touch to controller 310. In typical applications, the manner in which the sensing of touch is measured, tuned, and/or filtered may be configured by controller 310. In addition, controller 310 may recognize one or more gestures based on the sensed touch or touches. Controller 310 provides host 320 with touch or gesture information corresponding to the sensed touch or touches. Host 320 may use this touch or gesture information as user input and respond in an appropriate manner. In this way, the user may interact with computing system 300 by touch or gestures on touch screen 100 (or 200).

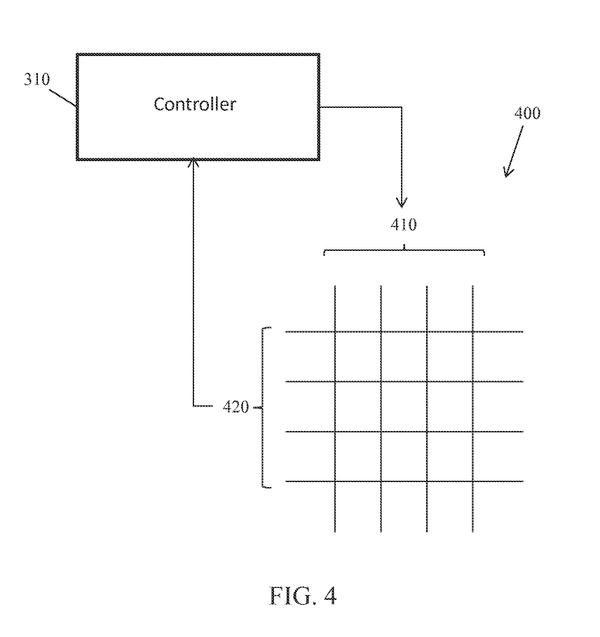

FIG. 4 shows a functional representation of a touch sensor as part of a touch screen in accordance with one or more embodiments of the present invention. In certain embodiments, a touch sensor 400 may be viewed as a plurality of column, or transmit, lines 410 and a plurality of row, or receive, lines 420 arranged as a mesh grid. The number of transmit lines 410 and the number of receive lines 420 may not be the same and may vary based on an application or a design. The apparent intersection of transmit lines 410 and receive lines 420 may be viewed as uniquely addressable locations of touch sensor 400. In operation, controller 310 may electrically drive one or more transmit lines 410 and touch sensor 400 may sense touch on one or more receive lines 420 sampled by controller 310. The role of transmit lines 410 and receive lines 420 may be reversed such that controller 310 electrically drives one or more receive lines 420 and touch sensor 400 may sense touch on one or more transmit lines 410 sampled by controller 310.

Controller 310 may interface with touch sensor 400 by a scanning process. In such an embodiment, controller 310 may electrically drive a selected transmit line 410 and sample all receive lines 420 that intersect the selected transmit line 410 by measuring, for example, capacitance at each intersection. This process may be continued through all transmit lines 410 such that capacitance is measured at each uniquely addressable location of touch sensor 400 at predetermined intervals. Controller 310 may allow for the adjustment of the scan rate depending on the needs of a particular design or application. Alternatively, controller 310 may interface with touch sensor 400 by an interrupt driven process. In such an embodiment, a touch or a gesture generates an interrupt to controller 310 that triggers controller 310 to read one or more of its own registers that store sensed touch information sampled from touch sensor 400 at predetermined intervals.

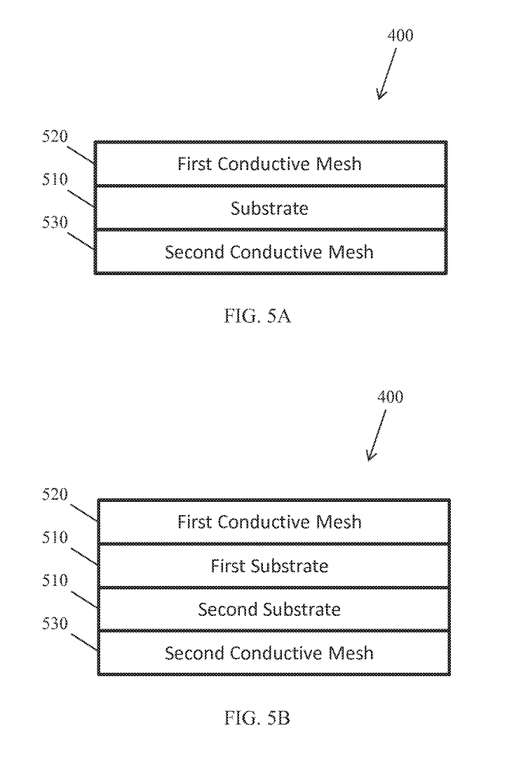

FIG. 5A shows a cross-section of a touch sensor with a single substrate in accordance with one or more embodiments of the present invention. A first conductive mesh 520 may be disposed on a top side of a substrate 510. A second conductive mesh 530 may be disposed on a bottom side of the substrate 510. In one or more embodiments of the present invention, substrate 510, first conductive mesh 520, and second conductive mesh 530 may form a touch sensor 400.

FIG. 5B shows a cross-section of a touch sensor with two substrates in accordance with one or more embodiments of the present invention. A first conductive mesh 520 may be disposed on a top side of a first substrate 510. A bottom side of the first substrate 510 may be laminated to a top side of a second substrate 510 with an optically clear adhesive (not shown) or an optically clear resin (not shown). A second conductive mesh 530 may be disposed on a bottom side of the second substrate 510. The substrates 510, first conductive mesh 520, and second conductive mesh 530 may form a touch sensor 400. One of ordinary skill in the art will recognize that the cross-sectional composition of a touch sensor may vary based on an application or a design in accordance with one or more embodiments of the present invention.

Transparent means the transmission of visible light with a transmittance rate of 85% or more. In certain embodiments, substrate 510 may be a transparent optically isotropic substrate composed of acrylic, triacetyl cellulose (“TAC”), cellulosic, cyclo-olefin polymer (“COP”), cycloaliphatic hydrocarbon, polycarbonate, polyethylene terephthalate glycol-modified (“PET-G”), or combinations thereof. In other embodiments, substrate 510 may be a transparent birefringent polyethylene terephthalate (“birefringent PET”). In still other embodiments, substrate 510 may be glass, plastic, or film.

In certain embodiments, first conductive mesh 520 may include a mesh of conductors that are partitioned so as to function as a plurality of distinct column, or transmit, lines (410 of FIG. 4). Second conductive mesh 530 may include a mesh of conductors that are partitioned so as to function as a plurality of distinct row, or receive, lines (420 of FIG. 4). In other embodiments, the roles played by the first conductive mesh 520 and the second conductive mesh 530 may be reversed. One of ordinary skill in the art will recognize that the configuration of first conductive mesh 520 and second conductive mesh 530 may vary based on an application or a design in accordance with one or more embodiments of the present invention.

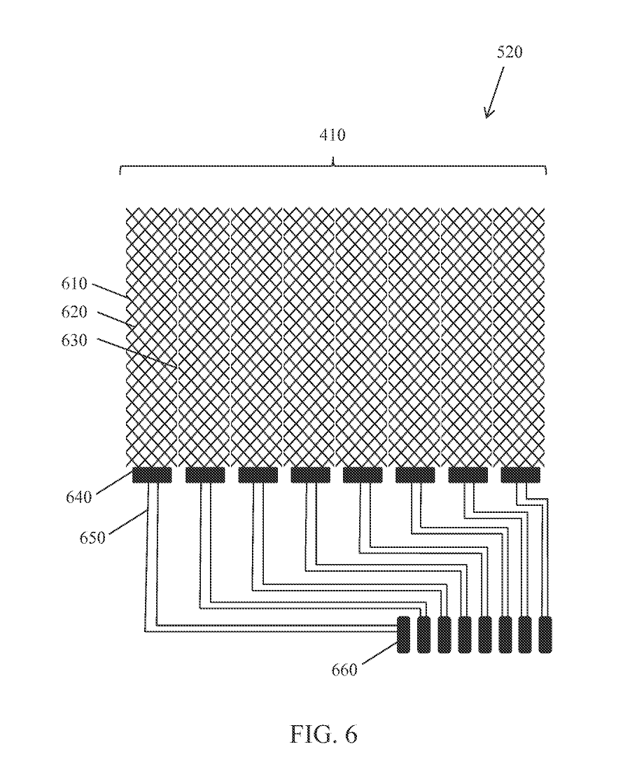

FIG. 6 shows a first conductive mesh disposed on a substrate in accordance with one or more embodiments of the present invention. First conductive mesh 520 may include a mesh formed by a plurality of parallel x-axis conductive lines 610 and a plurality of parallel y-axis conductive lines 620 disposed on a top side of a substrate (e.g., 510 of FIG. 5). One of ordinary skill in the art will recognize that a size of first conductive mesh 520 may vary based on an application or a design in accordance with one or more embodiments of the present invention.

In certain embodiments, the plurality of parallel x-axis conductors 610 may be substantially parallel to a predetermined x-axis (not shown) and the plurality of parallel y-axis conductors 620 may be substantially parallel to a predetermined y-axis (not shown). In other embodiments, the plurality of parallel x-axis conductors 610 may be angled relative to a predetermined x-axis and the plurality of parallel y-axis conductors 620 may be angled relative to a predetermined y-axis. One of ordinary skill in the art will recognize that the orientation of the plurality of parallel x-axis conductive lines 610 and the orientation of the plurality of parallel y-axis conductive lines 620 may vary based on an application or a design in accordance with one or more embodiments of the present invention.

In certain embodiments, the plurality of parallel x-axis conductive lines 610 may be perpendicular to the plurality of parallel y-axis conductive lines 620. In other embodiments, the plurality of parallel x-axis conductive lines 610 may be angled relative to the plurality of parallel y-axis conductive lines 620. One of ordinary skill in the art will recognize that the relative angle between the plurality of parallel x-axis conductive lines 610 and the plurality of parallel y-axis conductive lines 620 may vary based on an application or a design in accordance with one or more embodiments of the present invention.

In certain embodiments, a plurality of breaks 630 may partition first conductive mesh 620 into a plurality of column, or transmit, lines 410, each electrically partitioned from the others. Each transmit line 410 may route to a channel pad 640. Each channel pad 640 may route to an interface connector 660 by way of one or more interconnect conductive lines 650. Interface connectors 660 may provide a connection interface between the touch sensor and the controller.

In certain embodiments, one or more of the plurality of parallel x-axis conductors 610, the plurality of parallel y-axis conductors 620, the plurality of channel pads 640, the plurality of interconnect conductive lines 650, and/or the plurality of interface connectors 660 may be composed of silver nanowires, carbon nanotubes, graphene, conductive polymer, electroless plated catalytic ink, or any other conductive material suitable for use in a conductive mesh.

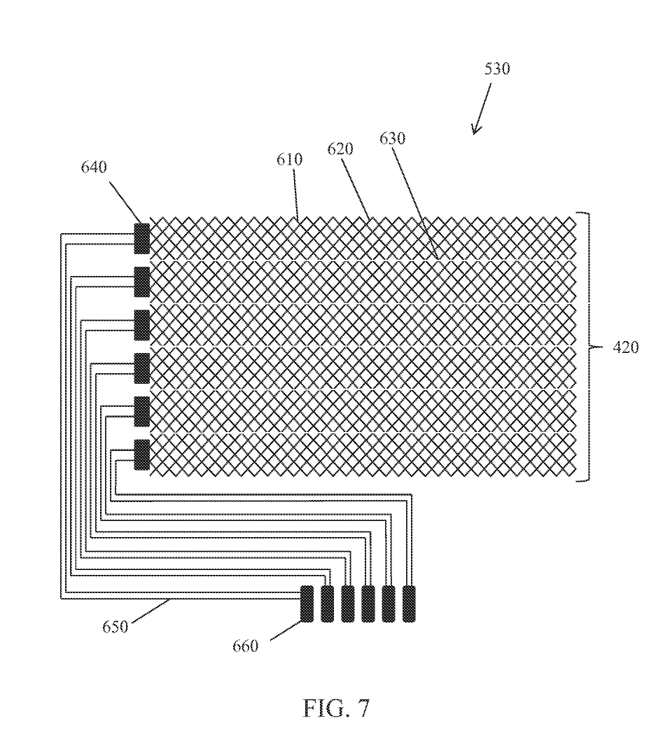

FIG. 7 shows a second conductive mesh disposed on a substrate in accordance with one or more embodiments of the present invention. Second conductive mesh 530 may include a mesh formed by a plurality of parallel x-axis conductive lines 610 and a plurality of parallel y-axis conductive lines 620 disposed on a second side of a substrate (e.g., 510 of FIG. 5). One of ordinary skill in the art will recognize that a size of the second conductive mesh 530 may vary based on an application or a design in accordance with one or more embodiments of the present invention. Typically, the second conductive mesh 530 is substantially similar in size to the first conductive mesh (520 of FIG. 6).

In certain embodiments, the plurality of parallel x-axis conductors 610 may be substantially parallel to a predetermined x-axis (not shown) and the plurality of parallel y-axis conductors 620 may be substantially parallel to a predetermined y-axis (not shown). In other embodiments, the plurality of parallel x-axis conductors 610 may be angled relative to a predetermined x-axis and the plurality of parallel y-axis conductors 620 may be angled relative to a predetermined y-axis. One of ordinary skill in the art will recognize that the orientation of the plurality of parallel x-axis conductive lines 610 and the orientation of the plurality of parallel y-axis conductive lines 620 may vary based on an application or a design in accordance with one or more embodiments of the present invention.

In certain embodiments, the plurality of parallel x-axis conductive lines 610 may be perpendicular to the plurality of parallel y-axis conductive lines 620. In other embodiments, the plurality of parallel x-axis conductive lines 610 may be angled relative to the plurality of parallel y-axis conductive lines 620. One of ordinary skill in the art will recognize that the relative angle between the plurality of parallel x-axis conductive lines 610 and the plurality of parallel y-axis conductive lines 620 may vary based on an application or a design in accordance with one or more embodiments of the present invention.

In certain embodiments, a plurality of breaks 630 may partition second conductive mesh 630 into a plurality of row, or receive, lines 420, each electrically partitioned from the others. Each receive line 420 may route to a channel pad 640. Each channel pad 640 may route to an interface connector 660 by way of one or more interconnect conductive lines 650. Interface connectors 660 may provide a connection interface between the touch sensor and the controller.

In certain embodiments, one or more of the plurality of parallel x-axis conductors 610, the plurality of parallel y-axis conductors 620, the plurality of channel pads 640, the plurality of interconnect conductive lines 650, and/or the plurality of interface connectors 660 may be composed of silver nanowires, carbon nanotubes, graphene, conductive polymer, electroless plated catalytic ink, or any other conductive material suitable for use in a conductive mesh.

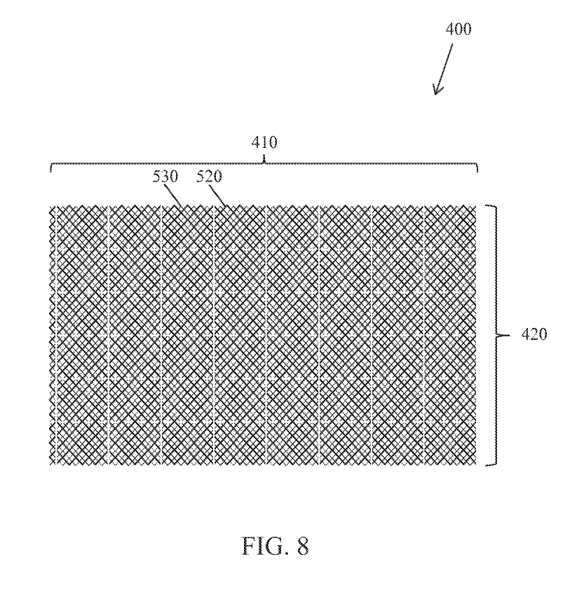

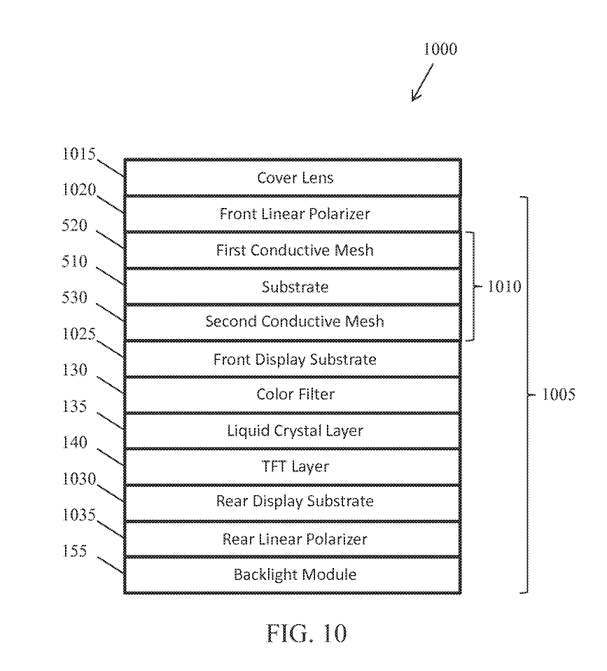

FIG. 8 shows a portion of a touch sensor in accordance with one or more embodiments of the present invention. In certain embodiments, a touch sensor 400 may be formed by disposing a first conductive mesh 520 on a first side of a substrate (e.g., 510 of FIG. 5) and disposing a second conductive mesh 530 on a second side of the substrate (e.g., 510 of FIG. 5). In other embodiments, the first conductive mesh 520 and the second conductive mesh 530 may be disposed as set out in the description that references FIGS. 10 through 15 of the present invention. The first conductive mesh 520 and the second conductive mesh 530 may be offset relative to one another. One of ordinary skill in the art will recognize that the offset between the first conductive mesh 520 and the second conductive mesh 530 may vary based on an application or a design in accordance with one or more embodiments of the present invention.

In certain embodiments, the first conductive mesh 520 may include a plurality of parallel x-axis conductive lines (610 of FIG. 6) and a plurality of parallel y-axis conductive lines (620 of FIG. 6) that form a mesh that is partitioned by a plurality of breaks (630 of FIG. 6) into electrically partitioned column, or transmit, lines 410. The second conductive mesh 530 may include a plurality of parallel x-axis conductive lines (610 of FIG. 7) and a plurality of parallel y-axis conductive lines (620 of FIG. 7) that form a mesh that is partitioned by a plurality of breaks (630 of FIG. 7) into electrically partitioned row, or receive, lines 420. In operation, a controller (310 of FIG. 3) may electrically drive one or more transmit lines 410 and touch sensor 400 senses touch on one or more receive lines 420 sampled by the controller (310 of FIG. 3). In other embodiments, the role of the first conductive mesh 520 and the second conductive mesh 530 may be reversed.

In certain embodiments, one or more of the plurality of parallel x-axis conductive lines (610 of FIG. 6 and FIG. 7), one or more of the plurality of parallel y-axis conductive lines (620 of FIG. 6 and FIG. 7), one or more of the plurality of breaks (630 of FIG. 6 and FIG. 7), one or more of the plurality of channel pads (640 of FIG. 6 and FIG. 7), one or more of the plurality of interconnect conductive lines (650 of FIG. 6 and FIG. 7), and/or one or more of the plurality of interface connectors (660 of FIG. 6 and FIG. 7) of the first conductive mesh 520 or second conductive mesh 530 may have different line widths and/or different orientations. In addition, the number of parallel x-axis conductive lines (610 of FIG. 6 and FIG. 7), the number of parallel y-axis conductive lines (620 of FIG. 6 and FIG. 7), and the line-to-line spacing between them may vary based on an application or a design. One of ordinary skill in the art will recognize that the size, configuration, and design of each conductive mesh may vary in accordance with one or more embodiments of the present invention.

In certain embodiments, one or more of the plurality of parallel x-axis conductive lines (610 of FIG. 6 and FIG. 7) and one or more of the plurality of parallel y-axis conductive lines (620 of FIG. 6 and FIG. 7) may have a line width less than approximately 5 micrometers. In other embodiments, one or more of the plurality of parallel x-axis conductive lines (610 of FIG. 6 and FIG. 7) and one or more of the plurality of parallel y-axis conductive lines (620 of FIG. 6 and FIG. 7) may have a line width in a range between approximately 5 micrometers and approximately 10 micrometers. In still other embodiments, one or more of the plurality of parallel x-axis conductive lines (610 of FIG. 6 and FIG. 7) and one or more of the plurality of parallel y-axis conductive lines (620 of FIG. 6 and FIG. 7) may have a line width in a range between approximately 10 micrometers and approximately 50 micrometers. In still other embodiments, one or more of the plurality of parallel x-axis conductive lines (610 of FIG. 6 and FIG. 7) and one or more of the plurality of parallel y-axis conductive lines (620 of FIG. 6 and FIG. 7) may have a line width greater than approximately 50 micrometers. One of ordinary skill in the art will recognize that the shape and width of one or more of the plurality of parallel x-axis conductive lines (610 of FIG. 6 and FIG. 7) and one or more of the plurality of parallel y-axis conductive lines (620 of FIG. 6 and FIG. 7) may vary in accordance with one or more embodiments of the present invention.

In certain embodiments, one or more of the plurality of channel pads (640 of FIG. 6 and FIG. 7), one or more of the plurality of interconnect conductive lines (650 of FIG. 6 and FIG. 7), and/or one or more of the plurality of interface connectors (660 of FIG. 6 and FIG. 7) may have a different width or orientation. In addition, the number of channel pads (640 of FIG. 6 and FIG. 7), interconnect conductive lines (650 of FIG. 6 and FIG. 7), and/or interface connectors (660 of FIG. 6 and FIG. 7) and the line-to-line spacing between them may vary based on an application or a design. One of ordinary skill in the art will recognize that the size, configuration, and design of each channel pad (640 of FIG. 6 and FIG. 7), interconnect conductive line (650 of FIG. 6 and FIG. 7), and/or interface connector (660 of FIG. 6 and FIG. 7) may vary in accordance with one or more embodiments of the present invention.

In typical applications, each of the one or more channel pads (640 of FIG. 6 and FIG. 7), interconnect conductive lines (650 of FIG. 6 and FIG. 7), and/or interface connectors (660 of FIG. 6 and FIG. 7) have a width substantially larger than each of the plurality of parallel x-axis conductive lines (610 of FIG. 6 and FIG. 7) or each of the plurality of parallel y-axis conductive lines (620 of FIG. 6 and FIG. 7). One of ordinary skill in the art will recognize that the size, configuration, and design as well as the number, shape, and width of channel pads (640 of FIG. 6 and FIG. 7), interconnect conductive lines (650 of FIG. 6 and FIG. 7), and/or interface connectors (660 of FIG. 6 and FIG. 7) may vary based on an application or a design in accordance with one or more embodiments of the present invention.

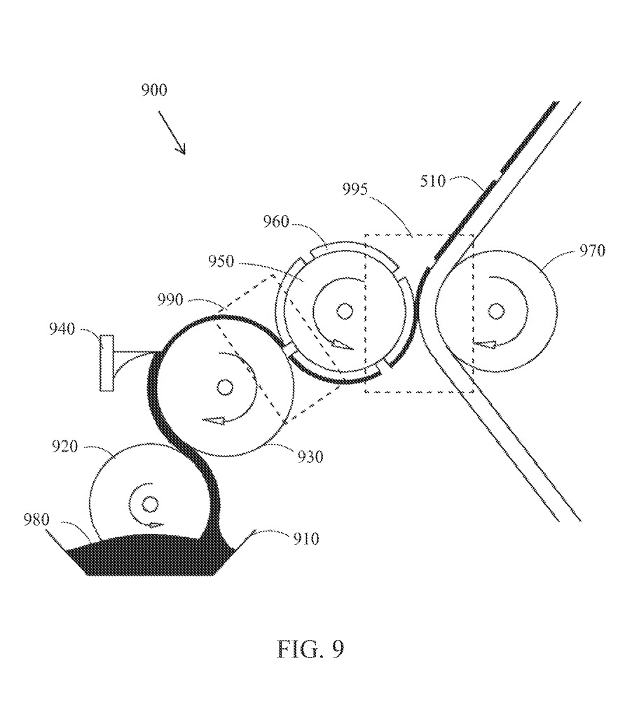

FIG. 9 shows a flexographic printing station in accordance with one or more embodiments of the present invention. Flexographic printing station 900 may include an ink pan 910, an ink roll 920 (also referred to as a fountain roll), an anilox roll 930 (also referred to as a meter roll), a doctor blade 940, a printing plate cylinder 950, a flexographic printing plate 960, and an impression cylinder 970.

In operation, ink roll 920 transfers ink 980 from ink pan 910 to anilox roll 930. In certain embodiments, ink 980 may be a precursor ink, catalytic ink, or catalytic alloy ink that serves as a plating seed suitable for metallization by electroless plating or other buildup process. In other embodiments, ink 980 may be a direct-print conductive ink that does not require metallization or further buildup. In still other embodiments, ink 980 may be any other conductive or precursor ink. One of ordinary skill in the art will recognize that the composition of ink 980 may vary based on an application or a design. Anilox roll 930 is typically constructed of a steel or aluminum core that may be coated by an industrial ceramic whose surface contains a plurality of very fine dimples, also referred to as cells (not shown). Doctor blade 940 removes excess ink 980 from anilox roll 930. In transfer area 990, anilox roll 930 meters the amount of ink 980 transferred to flexographic printing plate 960 to a uniform thickness. Printing plate cylinder 950 may be made of metal and the surface may be plated with chromium, or the like, to provide increased abrasion resistance. Flexographic printing plate 960 may be mounted to printing plate cylinder 950 by an adhesive (not shown).

One or more substrates 510 move between printing plate cylinder 950 and impression cylinder 970. Impression cylinder 970 applies pressure to printing plate cylinder 950, transferring an image from the embossing patterns of flexographic printing plate 960 onto substrate 510 at transfer area 995. The rotational speed of printing plate cylinder 950 is synchronized to match the speed at which substrate 510 moves through flexographic printing system 900. The speed may vary between 20 feet per minute to 750 feet per minute.

In one or more embodiments of the present invention, flexographic printing station 900 may be used to print a precursor or catalyst ink (not shown) image of one or more conductive meshes (520 or 530 of FIG. 8) on one or more sides of one or more substrates 510. In certain embodiments, subsequent to flexographic printing, the precursor or catalyst ink (not shown) may be metallized by an electroless plating process or other buildup process, forming one or more conductive meshes (520 or 530 of FIG. 8) on one or more substrates 510. In other embodiments, the ink may be a direct-printed (dense metal-filled) conductive ink 980 that may not require electroless plating or buildup. The one or more conductive meshes (520 or 530 of FIG. 8) on one or more substrates 510 may be used to form a touch sensor (400 of FIG. 8).

In one or more embodiments of the present invention, one or more flexographic printing stations 900 may be used to print each of the one or more conductive meshes (520 or 530 of FIG. 8). Each of the one or more flexographic printing stations uses a flexographic printing plate, sometimes referred to as a flexo master, to transfer an ink image to a substrate. The flexographic printing plate includes one or more embossing patterns, or raised projections, that have distal ends onto which ink or other printable material may be deposited. In operation, the inked flexographic printing plate prints an ink image of the one or more embossing patterns to the substrate. In certain embodiments, one or more flexographic printing stations may be used to print each of the first conductive mesh (520 of FIG. 6) and the second conductive mesh (530 of FIG. 7) on one or more substrates 510. While flexographic printing processes may be used to form one or more conductive meshes of a touch sensor, any other process capable of producing one or more conductive meshes may be used in accordance with one or more embodiments of the present invention.

In a conventional touch screen with a discrete touch sensor solution (e.g., FIG. 1 or FIG. 2) where the touch sensor (e.g., 110 of FIG. 1 or 210 of FIG. 2) is disposed over the display device sub-assembly (e.g., LCD 105 or OLED 205), the conductive meshes may exhibit specular reflectance when viewed from certain angles, such as, for example, oblique angles. Under normal operating conditions, such as, for example, typical user distances from the display device, this specular reflectance is typically only visible when the display device is not emitting light or is otherwise turned off. However, the conductive meshes may still be visible to the user when the display device is inspected closely. In an effort to reduce the specular reflectance exhibited by the conductive meshes in discrete touch sensor solutions, the width and pitch of the conductive lines may be constrained to reduce their visibility. These constraints may limit applications or designs in which a discrete touch sensor solution may be used, such as, for example, large touch screens.

In one or more embodiments of the present invention, a touch screen with conductive mesh under polarizer reduces or eliminates the visibility of the conductive mesh under normal operating conditions and close inspection by a user. In one or more embodiments of the present invention, a touch screen with a conductive mesh under polarizer reduces or eliminates specular reflectance that occurs when a conductive mesh is disposed over a display device sub-assembly. In these embodiments, rather than applying a discrete touch sensor solution over an existing display device sub-assembly, a new type of display device integrates a conductive mesh touch sensor in the display device itself under the polarizer or cover lens, as the case may be.

FIG. 10 shows a cross section of an LCD touch screen with conductive mesh under polarizer in accordance with one or more embodiments of the present invention. Touch screen 1000 includes LCD 1005 and a touch sensor 1010 that is integrated into the display device sub-assembly under the polarizer.

A top side of cover lens 1015 faces the user and may be composed of glass, plastic, film, or combinations thereof. A bottom side of cover lens 1015 may be coupled to a top side of a front linear polarizer 1020 by an optically clear adhesive (not shown) or an optically clear resin (not shown). Front linear polarizer 1020 is an anti-glare, or matte finish, polarizer. Front linear polarizer 1020 is composed of an optically isotropic film or other material that exhibits substantially uniform optical properties, such as reflectance and transmittance, in all directions. Anti-glare polarizers provide an anti-glare function and are typically easier to bond to cover lens 1015. Front linear polarizer 1020 may be rotated 90 degrees with respect to a rear linear polarizer 1035, thereby forming a cross-polarized pair.

A touch sensor 1010 includes a first conductive mesh 520 disposed on a top side of an optically isotropic substrate 510 and a second conductive mesh 530 disposed on a bottom side of the optically isotropic substrate 510. A top side of first conductive mesh 520 may be coupled to a bottom side of front linear polarizer 1020 by an optically clear adhesive (not shown) or an optically clear resin (not shown). A bottom side of second conductive mesh 530 may be coupled to a top side of a front display substrate 1025 by an optically clear adhesive (not shown) or an optically clear resin (not shown). Front display substrate 1025 may be composed of glass, plastic, film, or combinations thereof. A color filter 130 may be disposed on a bottom side of front display substrate 1025. Color filter 130 includes a plurality of RGB sub-pixel patterns (not shown). A liquid crystal layer 135 may be disposed between a bottom side of color filter 130 and a top side of TFT layer 140 and sealed by a sealant. TFT layer 140 may be disposed on a top side of a rear display substrate 1030 and is configured to selectively drive sub-pixel electrodes (not shown) of liquid crystal layer 135. Rear display substrate 1030 may be composed of glass, plastic, film, or combinations thereof. A top side of rear linear polarizer 1035 may be coupled to a bottom side of rear display substrate 1030 by an optically clear adhesive (not shown) or an optically clear resin (not shown). Rear linear polarizer 1035 may be a glossy or an anti-glare polarizer composed of an optically isotropic film or other material that exhibits substantially uniform optical properties, such as reflectance and transmittance, in all directions. A top side of backlight module 155 may be coupled to a bottom side of rear linear polarizer 1035. Backlight module 155 may include a light source such as an electroluminescent lamp, a cold cathode fluorescent lamp, or LED array

While touch sensor 1010 has been described as comprising a single substrate 510, one of ordinary skill in the art will recognize that a touch sensor comprising two substrates 510, such as that depicted in FIG. 5B, may be used in accordance with one or more embodiments of the present invention.

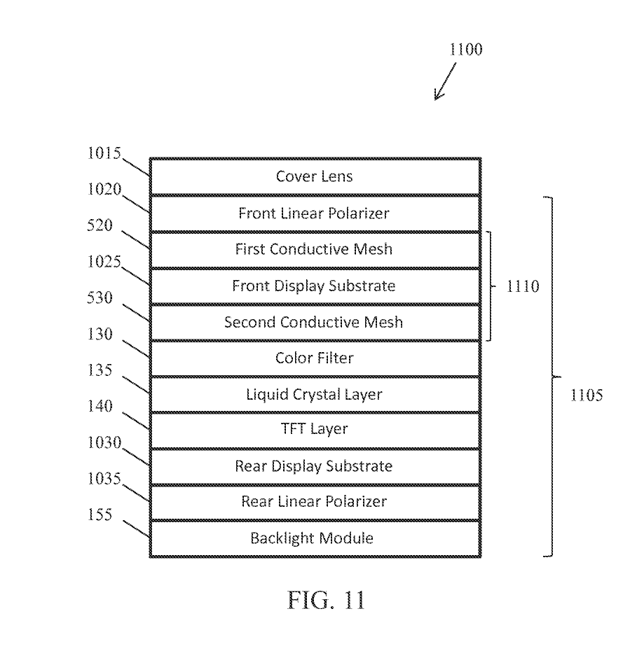

FIG. 11 shows a cross section of an LCD touch screen with conductive mesh under polarizer in accordance with one or more embodiments of the present invention. Touch screen 1100 includes LCD 1105 and a touch sensor 1110 that is integrated into the display device sub-assembly under the polarizer.

A top side of cover lens 1015 faces the user and may be composed of glass, plastic, film, or combinations thereof. A bottom side of cover lens 1015 may be coupled to a top side of a front linear polarizer 1020 by an optically clear adhesive (not shown) or an optically clear resin (not shown). Front linear polarizer 1020 is an anti-glare, or matte finish, polarizer. Front linear polarizer 1020 is composed of an optically isotropic film or other material that exhibits substantially uniform optical properties, such as reflectance and transmittance, in all directions. Anti-glare polarizers provide an anti-glare function and are typically easier to bond to cover lens 1015. Front linear polarizer 1020 may be rotated 90 degrees with respect to a rear linear polarizer 1035, thereby forming a cross-polarized pair.

A touch sensor 1110 includes a first conductive mesh 520 disposed on a top side of front display substrate 1025 and a second conductive mesh 530 disposed on a bottom side of front display substrate 1025. A top side of first conductive mesh 520 may be coupled to a bottom side of front linear polarizer 1020 by an optically clear adhesive (not shown) or an optically clear resin (not shown). Front display substrate 1025 may be composed of glass, plastic, film, or combinations thereof. A color filter 130 may be disposed on a bottom side of second conductive mesh 530. Color filter 130 includes a plurality of RGB sub-pixel patterns (not shown). A liquid crystal layer 135 may be disposed between a bottom side of color filter 130 and a top side of TFT layer 140 and sealed by a sealant. TFT layer 140 may be disposed on a top side of a rear display substrate 1030 and may be configured to selectively drive sub-pixel electrodes (not shown) of liquid crystal layer 135. Rear display substrate 1030 may be composed of glass, plastic, film, or combinations thereof. A top side of rear linear polarizer 1035 may be coupled to a bottom side of rear display substrate 1030 by an optically clear adhesive (not shown) or an optically clear resin (not shown). Rear linear polarizer 1035 may be a glossy or an anti-glare polarizer composed of an optically isotropic film or other material that exhibits substantially uniform optical properties, such as reflectance and transmittance, in all directions. A top side of backlight module 155 may be coupled to a bottom side of rear linear polarizer 1035. Backlight module 155 may include a light source such as an electroluminescent lamp, a cold cathode fluorescent lamp, or LED array

Because touch sensor 1110 has moved down the stack, the potential exists that noise at harmonics of the scan rate of display device 1105 will reduce the signal-to-noise ratio of touch sensor 1110 and interfere with the operation of touch sensor 1110. However, because touch sensor 1110 may be comprised of conductive meshes with low conductivity, a scan rate of touch sensor 1110 may be increased to a fast rate that minimizes the introduction of noise from the scan rate of display device 1105.

In certain embodiments discussed above, touch sensor 1110 includes first conductive mesh 520 disposed on the top side of front display substrate 1025 and second conductive mesh 530 disposed on the bottom side of front display substrate 1025. As a consequence, when compared to, for example, touch screen 1000 of FIG. 10, a substrate layer (e.g., 510 of FIG. 5) may be removed, the manufacture of touch screen 1100 may be simplified, and the overall thickness of display device 1105 may be reduced.

However, in other embodiments (not independently illustrated), a first conductive mesh 520 may be disposed on a top side of a substrate layer (510 of FIG. 5) and a second conductive 530 may be disposed on a top side of front display substrate 1025. In such an embodiment, a bottom side of front linear polarizer 1020 may be coupled to a top side of first conductive mesh 520 by an optically clear adhesive (not shown) or an optically clear resin (not shown). A bottom side of the substrate layer (510 of FIG. 5) may be coupled to a top side of second conductive mesh 530 disposed on a top side of front display substrate 1025. One of ordinary skill in the art will recognize that the allocation of conductive meshes may vary in accordance with one or more embodiments of the present invention.

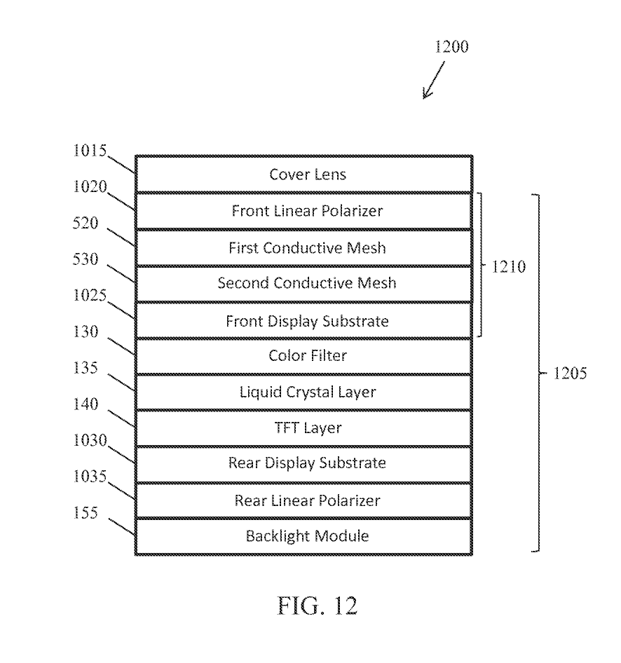

FIG. 12 shows a cross section of an LCD touch screen with conductive mesh under polarizer in accordance with one or more embodiments of the present invention. Touch screen 1200 includes LCD 1205 and a touch sensor 1210 that is integrated into the display device sub-assembly under the polarizer.

A top side of cover lens 1015 faces the user and may be composed of glass, plastic, film, or combinations thereof. A bottom side of cover lens 1015 may be coupled to a top side of a front linear polarizer 1020 by an optically clear adhesive (not shown) or an optically clear resin (not shown). Front linear polarizer 1020 is an anti-glare, or matte finish, polarizer. Front linear polarizer 1020 is composed of an optically isotropic film or other material that exhibits substantially uniform optical properties, such as reflectance and transmittance, in all directions. Anti-glare polarizers provide an anti-glare function and are typically easier to bond to cover lens 1015. Front linear polarizer 1020 may be rotated 90 degrees with respect to a rear linear polarizer 1035, thereby forming a cross-polarized pair.

A touch sensor 1210 includes a first conductive mesh 520 disposed on a bottom side of front linear polarizer 1020 and a second conductive mesh 530 disposed on a top side of front display substrate 1025. A bottom side of first conductive mesh 520 may be coupled to a top side of second conductive mesh 530 by an optically clear adhesive (not shown) or an optically clear resin (not shown). Front display substrate 1025 may be composed of glass, plastic, film, or combinations thereof. A color filter 130 may be disposed on a bottom side of front display substrate 1025. Color filter 130 includes a plurality of RGB sub-pixel patterns (not shown). A liquid crystal layer 135 may be disposed between a bottom side of color filter 130 and a top side of TFT layer 140 and sealed by a sealant. TFT layer 140 may be disposed on a top side of a rear display substrate 1030 and may be configured to selectively drive sub-pixel electrodes (not shown) of liquid crystal layer 135. Rear display substrate 1030 may be composed of glass, plastic, film, or combinations thereof. A top side of rear linear polarizer 1035 may be coupled to a bottom side of rear display substrate 1030 by an optically clear adhesive (not shown) or an optically clear resin (not shown). Rear linear polarizer 1035 may be a glossy or an anti-glare polarizer composed of an optically isotropic film or other material that exhibits substantially uniform optical properties, such as reflectance and transmittance, in all directions. A top side of backlight module 155 may be coupled to a bottom side of rear linear polarizer 1035. Backlight module 155 may include a light source such as an electroluminescent lamp, a cold cathode fluorescent lamp, or LED array

Because touch sensor 1210 has moved down the stack, the potential exists that noise at harmonics of the scan rate of display device 1205 will reduce the signal-to-noise ratio of touch sensor 1210 and interfere with the operation of touch sensor 1210. However, because touch sensor 1210 may be comprised of conductive meshes with low conductivity, a scan rate of touch sensor 1210 may be increased to a fast rate that minimizes the introduction of noise from the scan rate of display device 1205.

In certain embodiments discussed above, touch sensor 1210 includes first conductive mesh 520 disposed on the bottom side of front linear polarizer 1020 and second conductive mesh 530 disposed on the top side of front display substrate 1025. As a consequence, when compared to, for example, touch screen 1000 of FIG. 10, a substrate layer (e.g., 510 of FIG. 5) may be removed, the manufacture of touch screen 1200 may be simplified, and the overall thickness of display device 1205 may be reduced.

However, in other embodiments (not independently illustrated), a first conductive mesh 520 may be disposed on a bottom side of front linear polarizer 1020 and a second conductive mesh may be disposed on a bottom side of a substrate layer (510 of FIG. 5). In such an embodiment, a bottom side of the first conductive mesh 520 disposed on the bottom side of front linear polarizer 1020 may be coupled to a top side of the substrate layer (510 of FIG. 5) by an optically clear adhesive (not shown) or optically clear resin (not shown). A bottom side of the second conductive mesh disposed on the bottom side of the substrate layer (510 of FIG. 5) may be coupled to a top side of a front display substrate 1025 by an optically clear adhesive (not shown) or an optically clear resin (not shown). In still other embodiments, a first conductive mesh 520 may be disposed on a top side of a substrate layer (510 of FIG. 5) and a second conductive mesh may be disposed on a top side of front display substrate 1025. In such an embodiment, a bottom side of a front linear polarizer 1020 may be coupled to first conductive mesh 520 disposed on a top side of the substrate layer (510 of FIG. 5) by an optically clear adhesive (not shown) or an optically clear resin (not shown). A bottom side of the substrate layer (510 of FIG. 5) may be coupled to a top side of a second conductive mesh 530 disposed on a top side of a front display substrate 1025 by an optically clear adhesive (not shown) or an optically clear resin (not shown). One of ordinary skill in the art will recognize that the allocation of conductive meshes may vary in accordance with one or more embodiments of the present invention.

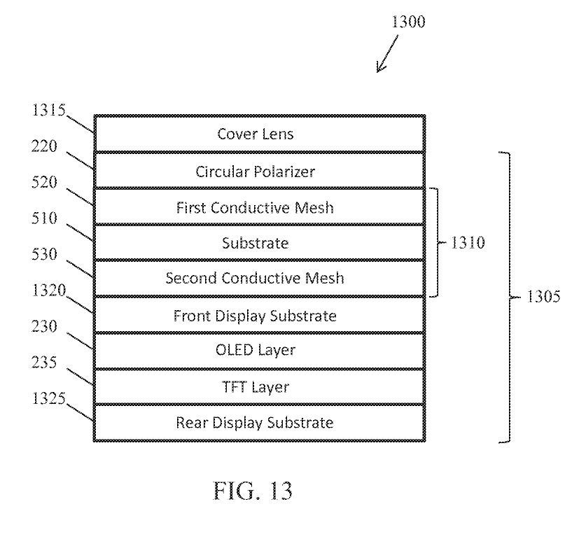

FIG. 13 shows a cross section of an OLED touch screen with a conductive mesh under a polarizer in accordance with one or more embodiments of the present invention. Touch screen 1300 includes OLED display 1305 and a touch sensor 1310 that is integrated into the display device sub-assembly under the polarizer.

A top side of cover lens 1315 faces the user and may be composed of glass, plastic, film, or combinations thereof. A bottom side of cover lens 1315 may be coupled to a top side of a circular polarizer 220 by an optically clear adhesive (not shown) or an optically clear resin (not shown). Circular polarizer 220 is an anti-glare (matte finish) polarizer.

A touch sensor 1310 includes a first conductive mesh 520 disposed on a top side of a substrate 510 and a second conductive mesh 530 disposed on a bottom side of substrate 510. Substrate 510 may be composed of an optically isotropic material or a birefringent PET material. A top side of first conductive mesh 520 may be coupled to a bottom side of circular polarizer 220 by an optically clear adhesive (not shown) or an optically clear resin (not shown). A bottom side of second conductive mesh 530 may be coupled to a top side of front display substrate 1320 by an optically clear adhesive (not shown) or an optically clear resin (not shown). Front display substrate 1320 may be composed of glass, plastic, film, or combinations thereof. An OLED layer 230 may be disposed between a bottom side of front display substrate 1320 and a top side of a TFT layer 235. TFT layer 235 may be disposed on a top side of a rear display substrate 1325 and may be configured to selectively drive OLED sub-pixels (not shown). Rear display substrate 1325 may be composed of glass, plastic, film, or combinations thereof.

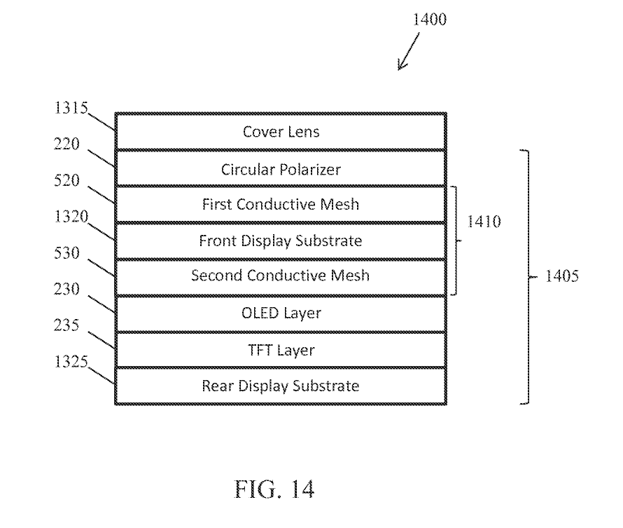

FIG. 14 shows a cross section of an OLED touch screen with a conductive mesh under a polarizer in accordance with one or more embodiments of the present invention. Touch screen 1400 includes OLED display 1405 and a touch sensor 1410 that is integrated into the display device sub-assembly under the polarizer.

A top side of cover lens 1315 faces the user and may be composed of glass, plastic, film, or combinations thereof. A bottom side of cover lens 1315 may be coupled to a top side of a circular polarizer 220 by an optically clear adhesive (not shown) or an optically clear resin (not shown). Circular polarizer 220 is an anti-glare (matte finish) polarizer.

A touch sensor 1410 includes a first conductive mesh 520 disposed on a top side of a front display substrate 1320 and a second conductive mesh 530 disposed on a bottom side of front display substrate 1320. Front display substrate 1320 may be composed of glass, plastic, film, or combinations thereof. A top side of first conductive mesh 520 may be coupled to a bottom side of circular polarizer 220 by an optically clear adhesive (not shown) or an optically clear resin (not shown). An OLED layer 230 may be disposed between a bottom side of second conductive mesh 530 and a top side of a TFT layer 235. TFT layer 235 may be disposed on a top side of a rear display substrate 1325 and may be configured to selectively drive OLED sub-pixels (not shown). Rear display substrate 1325 may be composed of glass, plastic, film, or combinations thereof.

Because touch sensor 1410 has moved down the stack, the potential exists that noise at harmonics of the scan rate of display device 1405 will reduce the signal-to-noise ratio of touch sensor 1410 and interfere with the operation of touch sensor 1410. However, because touch sensor 1410 may be comprised of conductive meshes with low conductivity, a scan rate of touch sensor 1410 may be increased to a fast rate that minimizes the introduction of noise from the scan rate of display device 1405.

In certain embodiments discussed above, touch sensor 1410 includes first conductive mesh 520 disposed on the top side of front display substrate 1320 and second conductive mesh 530 disposed on the bottom side of front display substrate 1320. As a consequence, when compared to, for example, touch screen 1300 of FIG. 13, a substrate layer (e.g., 510 of FIG. 5) may be removed, the manufacture of touch screen 1400 may be simplified, and the overall thickness of display device 1405 may be reduced.

However, in other embodiments (not independently illustrated), a first conductive mesh 520 may be disposed on a top side of a substrate layer (510 of FIG. 5) and second conductive 530 may be disposed on a top side of front display substrate 1320. In such an embodiment, a bottom side of circular polarizer 220 may be coupled to a top side of first conductive mesh 520 by an optically clear adhesive (not shown) or an optically clear resin (not shown). A bottom side of the substrate layer (510 of FIG. 5) may be coupled to a top side of second conductive mesh 530 disposed on a top side of front display substrate 1320 by an optically clear adhesive (not shown) or an optically clear resin (not shown). One of ordinary skill in the art will recognize that the allocation of conductive meshes may vary in accordance with one or more embodiments of the present invention.

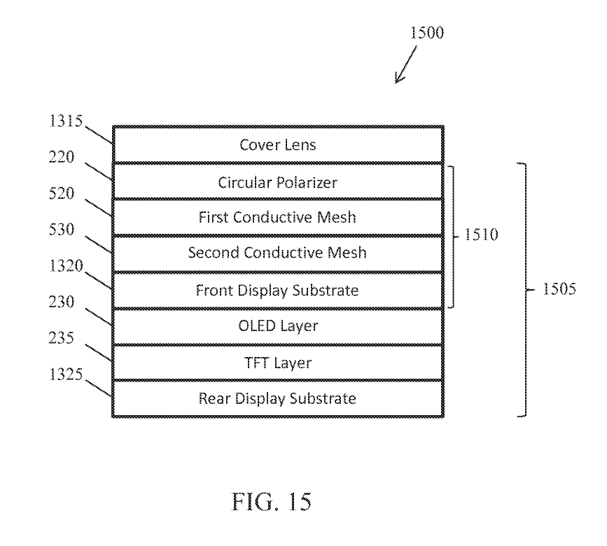

FIG. 15 shows a cross section of an OLED touch screen with a conductive mesh under a polarizer in accordance with one or more embodiments of the present invention. Touch screen 1500 includes OLED display 1505 and a touch sensor 1510 that is integrated into the display device sub-assembly under the polarizer.

A top side of cover lens 1315 faces the user and may be composed of glass, plastic, film, or combinations thereof. A bottom side of cover lens 1315 may be coupled to a top side of a circular polarizer 220 by an optically clear adhesive (not shown) or an optically clear resin (not shown). Circular polarizer 220 is an anti-glare (matte finish) polarizer.

A touch sensor 1510 includes a first conductive mesh 520 disposed on a bottom side of circular polarizer 220 and a second conductive mesh 530 disposed on a top side of front display substrate 1320. Front display substrate 1320 may be composed of glass, plastic, film, or combinations thereof. A bottom side of first conductive mesh 520 may be coupled to a top side of second conductive mesh 530 by an optically clear adhesive (not shown) or an optically clear resin (not shown). An OLED layer 230 may be disposed between a bottom side of front display substrate 1320 and a top side of a TFT layer 235. TFT layer 235 may be disposed on a top side of a rear display substrate 1325 and may be configured to selectively drive OLED sub-pixels (not shown). Rear display substrate 1325 may be composed of glass, plastic, film, or combinations thereof.

Because touch sensor 1510 has moved down the stack, the potential exists for noise at harmonics of the scan rate of the display device 1505 that reduces the signal-to-noise ratio of touch sensor 1510 and interferes with the operation of touch sensor 1510. However, because touch sensor 1510 may be comprised of conductive meshes with low conductivity, a scan rate of touch sensor 1510 may be increased to a fast rate that minimizes the introduction of noise from the scan rate of display device 1505.

In certain embodiments discussed above, touch sensor 1510 includes first conductive mesh 520 disposed on the bottom side of circular polarizer 220 and second conductive mesh 530 disposed on the top side of front display substrate 1320. As a consequence, when compared to, for example, touch screen 1300 of FIG. 13, a substrate layer (e.g., 510 of FIG. 5) may be removed, the manufacture of touch screen 1500 may be simplified, and the overall thickness of display device 1505 may be reduced.

However, in other embodiments (not independently illustrated), a first conductive mesh 520 may be disposed on a bottom side of circular polarizer 220 and a second conductive mesh may be disposed on a bottom side of a substrate layer (510 of FIG. 5). In such an embodiment, a bottom side of the first conductive mesh 520 disposed on the bottom side of circular polarizer 220 may be coupled to a top side of the substrate layer (510 of FIG. 5) by an optically clear adhesive (not shown) or optically clear resin (not shown). A bottom side of the second conductive mesh disposed on the bottom side of the substrate layer (510 of FIG. 5) may be coupled to a top side of a front display substrate 1320 by an optically clear adhesive (not shown) or an optically clear resin (not shown). In still other embodiments, a first conductive mesh 520 may be disposed on a top side of a substrate layer (510 of FIG. 5) and a second conductive mesh may be disposed on a top side of front display substrate 1320. In such an embodiment, a bottom side of a circular polarizer 220 may be coupled to first conductive mesh 520 disposed on a top side of the substrate layer (510 of FIG. 5) by an optically clear adhesive (not shown) or an optically clear resin (not shown). A bottom side of the substrate layer (510 of FIG. 5) may be coupled to a top side of a second conductive mesh 530 disposed on a top side of a front display substrate 1025 by an optically clear adhesive (not shown) or an optically clear resin (not shown). One of ordinary skill in the art will recognize that the allocation of conductive meshes may vary in accordance with one or more embodiments of the present invention.

Advantages of one or more embodiments of the present invention may include one or more of the following:

In one or more embodiments of the present invention, a touch screen with conductive mesh under polarizer reduces or eliminates the visibility of the conductive meshes.

In one or more embodiments of the present invention, a touch screen with conductive mesh under polarizer reduces or eliminates the visibility of the conductive meshes under reflected light.

In one or more embodiments of the present invention, a touch screen with conductive mesh under polarizer reduces or eliminates the visibility of the conductive meshes when an underlying backlight module or OLEDs are not emitting light.

In one or more embodiments of the present invention, a touch screen with conductive mesh under polarizer reduces or eliminates the Moiré effect that may otherwise enhance the visibility of the conductive meshes.

In one or more embodiments of the present invention, a touch screen with conductive mesh under polarizer allows for the use of wider conductive lines while reducing or eliminating the visibility of the conductive meshes.

In one or more embodiments of the present invention, a touch screen with conductive mesh under polarizer allows for the use of conductive lines disposed at a larger pitch while reducing or eliminating the visibility of the conductive meshes.

In one or more embodiments of the present invention, a touch screen with conductive mesh under polarizer allows for the use of a touch sensor with larger displays while reducing or eliminating the visibility of the conductive meshes.

In one or more embodiments of the present invention, a touch screen with conductive mesh under polarizer provides touch sensor performance similar to or better than conventional discrete touch sensor implementations.

In one or more embodiments of the present invention, a touch screen with conductive mesh under polarizer improves touch sensor reliability compared to conventional discrete touch sensor implementations.

In one or more embodiments of the present invention, a touch screen with conductive mesh under polarizer reduces the cost associated with manufacturing the touch screen compared to conventional discrete touch sensor implementations.

In one or more embodiments of the present invention, a touch screen with conductive mesh under polarizer simplifies the process of manufacturing the touch screen compared to conventional discrete touch sensor implementations.

In one or more embodiments of the present invention, a touch screen with conductive mesh under polarizer uses a touch sensor that is compatible with flexographic printing processes.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A touch screen comprising:
a front linear polarizer;
a touch sensor; and
a front display substrate,
wherein the touch sensor comprises a first conductive mesh disposed on a top side of an optically isotropic substrate and a second conductive mesh disposed on a bottom side of the optically isotropic substrate,
wherein a top side of the first conductive mesh is coupled to a bottom side of the front linear polarizer, and
wherein and a bottom side of the second conductive mesh is coupled to a top side of the front display substrate.

2. The touch screen of claim 1, further comprising:
a cover lens coupled to a top side of the front linear polarizer;
a color filter disposed on a bottom side of the front display substrate;
a liquid crystal layer disposed between a bottom side of the color filter and a top side of a thin-film transistor layer, wherein the thin-film transistor layer is disposed on a top side of a rear display substrate;
a rear linear polarizer, wherein a top side of the rear linear polarizer is coupled to a bottom side of the rear display substrate; and
a backlight module coupled to a bottom side of the rear linear polarizer.

3. The touch screen of claim 1,
wherein the top side of the first conductive mesh is coupled to the bottom side of the front linear polarizer with an optically clear adhesive or resin, and
wherein the bottom side of the second conductive mesh is coupled to the top side of the front display substrate with the optically clear adhesive or resin.

4. The touch screen of claim 1, wherein the front linear polarizer is an anti-glare polarizer.

5. A touch screen comprising:
a front linear polarizer;
a touch sensor; and
a front display substrate,
wherein the touch sensor comprises a first conductive mesh disposed on a top side of the front display substrate and a second conductive mesh disposed on a bottom side of the front display substrate,
wherein a top side of the first conductive mesh is coupled to a bottom side of the front linear polarizer.

6. The touch screen of claim 5, further comprising:
a cover lens coupled to a top side of the front linear polarizer;
a color filter disposed on a bottom side of the second conductive mesh;
a liquid crystal layer disposed between a bottom side of the color filter and a top side of a thin-film transistor layer, wherein the thin-film transistor layer is disposed on a top side of a rear display substrate;
a rear linear polarizer, wherein a top side of the rear linear polarizer is coupled to a bottom side of the rear display substrate; and
a backlight module coupled to a bottom side of the rear linear polarizer.

7. The touch screen of claim 5, wherein the top side of the first conductive mesh is coupled to the bottom side of the front linear polarizer with an optically clear adhesive or resin.

8. The touch screen of claim 5, wherein the front linear polarizer is an anti-glare polarizer.

9. A touch screen comprising:
a front linear polarizer;
a touch sensor; and
a front display substrate,
wherein the touch sensor comprises a first conductive mesh disposed on a bottom side of the front linear polarizer and a second conductive mesh disposed on a top side of the front display substrate, and
wherein a bottom side of the first conductive mesh is coupled to a top side of the second conductive mesh.

10. The touch screen of claim 9, further comprising:
a cover lens coupled to a top side of the front linear polarizer;
a color filter disposed on a bottom side of the front display substrate;
a liquid crystal layer disposed between a bottom side of the color filter and a top side of a thin-film transistor layer, wherein the thin-film transistor layer is disposed on a top side of a rear display substrate;
a rear linear polarizer, wherein a top side of the rear linear polarizer is coupled to a bottom side of the rear display substrate; and
a backlight module coupled to a bottom side of the rear linear polarizer.

11. The touch screen of claim 9, wherein the bottom side of the first conductive mesh is coupled to a top side of the second conductive mesh with an optically clear adhesive or resin.

12. The touch screen of claim 9, wherein the front linear polarizer is an anti-glare polarizer.

13. A touch screen comprising:
a circular polarizer;
a touch sensor; and
a front display substrate,
wherein the touch sensor comprises a first conductive mesh disposed on a top side of a substrate and a second conductive mesh disposed on a bottom side of the substrate,
wherein a top side of the first conductive mesh is coupled to a bottom side of the circular polarizer, and
wherein a bottom side of the second conductive mesh is coupled to a top side of the front display substrate.

14. The touch screen of claim 13, further comprising:
a cover lens coupled to a top side of the circular polarizer;
an organic light emitting diode layer disposed between a bottom side of the front display substrate and a top side of a thin-film transistor layer,
wherein the thin-film transistor layer is disposed on a top side of a rear display substrate.

15. The touch screen of claim 13,
wherein the top side of the first conductive mesh is coupled to the bottom side of the circular polarizer with an optically clear adhesive or resin, and
wherein the bottom side of the second conductive mesh is coupled to the top side of the front display substrate with the optically clear adhesive or resin.

16. The touch screen of claim 13, wherein the circular polarizer is an anti-glare polarizer.

17. The touch screen of claim 13, wherein the substrate is an optically isotropic film substrate.

18. The touch screen of claim 13, wherein the substrate is a birefringent PET substrate.

19. A touch screen comprising:
a circular polarizer;
a touch sensor; and
a front display substrate,
wherein the touch sensor comprises a first conductive mesh disposed on a top side of the front display substrate and a second conductive mesh disposed on a bottom side of the front display substrate,
wherein a top side of the first conductive mesh is coupled to a bottom side of the circular polarizer.

20. The touch screen of claim 19, further comprising:
a cover lens coupled to a top side of the circular polarizer;
an organic light emitting diode layer disposed between a bottom side of the second conductive mesh and a top side of a thin-film transistor layer,
wherein the thin-film transistor layer is disposed on a top side of a rear display substrate.

21. The touch screen of claim 19, wherein the top side of the first conductive mesh is coupled to the bottom side of the circular polarizer with an optically clear adhesive or resin.

22. The touch screen of claim 19, wherein the circular polarizer is an anti-glare polarizer.

23. A touch screen comprising:
a circular polarizer;
a touch sensor; and
a front display substrate,
wherein the touch sensor comprises a first conductive mesh disposed on a bottom side of the circular polarizer and a second conductive mesh disposed on a top side of the front display substrate, and
wherein a bottom side of the first conductive mesh is coupled to a top side of the second conductive mesh.

24. The touch screen of claim 23, further comprising:
a cover lens coupled to a top side of the circular polarizer;
an organic light emitting diode layer disposed between a bottom side of the front display substrate and a top side of a thin-film transistor layer,
wherein the thin-film transistor layer is disposed on a top side of a rear display substrate.

25. The touch screen of claim 23, wherein the bottom side of the first conductive mesh is coupled to the top side of the second conductive mesh with an optically clear adhesive or resin.

26. The touch screen of claim 23, wherein the circular polarizer is an anti-glare polarizer.
